(19) United States
(12) Patent Application Publication
(10) Pub. No.: US 2026/0047252 A1
(43) Pub. Date: Feb. 12, 2026

(54) SEMICONDUCTOR DEVICE INCLUDING A PLURALITY OF MICRO-LEDS

(71) Applicant: Infineon Technologies AG, Neubiberg (DE)

(72) Inventor: Dietrich Bonart, Bad Abbach (DE)

(21) Appl. No.: 19/293,615

(22) Filed: Aug. 7, 2025

(30) Foreign Application Priority Data
Aug. 8, 2024 (DE) 102024207545.0

(51) Int. Cl. H10H 29/14; H01L 25/16; H10H 20/812; H10H 29/85

(52) U.S. Cl. CPC H10H 29/142; H01L 25/167; H10H 20/812; H10H 29/857

(57) ABSTRACT

A semiconductor device is provided. The semiconductor device includes a semiconductor substrate that has an n-doped layer, a p-doped layer, and an active light emitting layer arranged between the n-doped layer and the p-doped layer. The semiconductor device further includes a plurality of micro-LEDs monolithically integrated in the semiconductor substrate. The plurality of micro-LEDs is arranged in a two-dimensional array along a first direction and along a second direction. The plurality of micro-LEDs comprises a first micro-LED that is surrounded by other micro-LEDs of the plurality of micro-LEDs. A corner associated with the first micro-LED does not comprise any cathode contact that is electrically connected to the n-doped layer.

### TECHNICAL FIELD

The present disclosure relates to semiconductor device including a plurality of micro-LEDs.

### BACKGROUND

Light-emitting diodes (LEDs) are semiconductor devices that convert an applied voltage into light by encouraging electron-hole recombination events in a semiconductor material. In turn, the energy released in the recombination event produces a photon. LEDs have a number of favorable characteristics, like robust physical characteristics, long lifetime, high reliability, and, depending on the material used, low cost. Therefore, LEDs are interesting for a variety of applications, like automotive lighting, interior lighting, or LED projection. For example, micro-LEDs may be arranged in an array configuration to provide a pixelated LED light source.

### SUMMARY

According to an embodiment of a semiconductor device, the semiconductor device comprises a semiconductor substrate that comprises an n-doped layer, a p-doped layer and an active light emitting layer arranged between the n-doped layer and the p-doped layer. The semiconductor device further comprises a plurality of micro-LEDs that are monolithically integrated in the semiconductor substrate. The plurality of micro-LEDs are arranged in a two-dimensional array along a first direction and along a second direction. The plurality of micro-LEDs comprise a first micro-LED that is surrounded by other micro-LEDs of the plurality of micro-LEDs. A corner associated with the first micro-LED does not comprise any cathode contact that is electrically connected to the n-doped layer.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1A and 1B illustrate partial top views of an exemplary semiconductor device,

FIG. 1C illustrates a cross-sectional view of the semiconductor device along the lines labelled A-A′ and B-B′ in FIGS. 1A and 1B, and FIG. 1D illustrates a cross-sectional view of the semiconductor device along the lines labelled C-C′ and D-D′ in FIGS. 1A and 1B;

FIGS. 2 through 5 illustrate partial top views of further exemplary semiconductor devices; and

FIGS. 6 and 7 illustrate partial cross-sectional views of semiconductor device arrangements.

### DETAILED DESCRIPTION

The making and using of several examples are discussed in detail below. It should be appreciated, however, that the present invention provides many applicable inventive concepts that can be embodied in a wide variety of specific contexts. The specific examples discussed are merely illustrative of specific ways to make and use the invention, and do not limit the scope of the invention.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The terms “on” and “over” are not to be construed as meaning only “directly on” and “directly over”. Rather, if one element is positioned “on” or “over” another element (e. g., a layer is “on” or “over” another layer or “on” or “over” a substrate), a further component (e. g., a further layer) may be positioned between the two elements (e. g., a further layer may be positioned between a layer and a substrate if the layer is “on” or “over” said substrate).

Spatially relative terms, such as “beneath”, “below”, “lower”, “above”, “upper”, “under” and the like, are used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “electrically connected” may describe a permanent low-resistive connection between electrically connected elements, for example a direct contact between the concerned elements or a low-resistive connection via a metal and/or heavily doped semiconductor material.

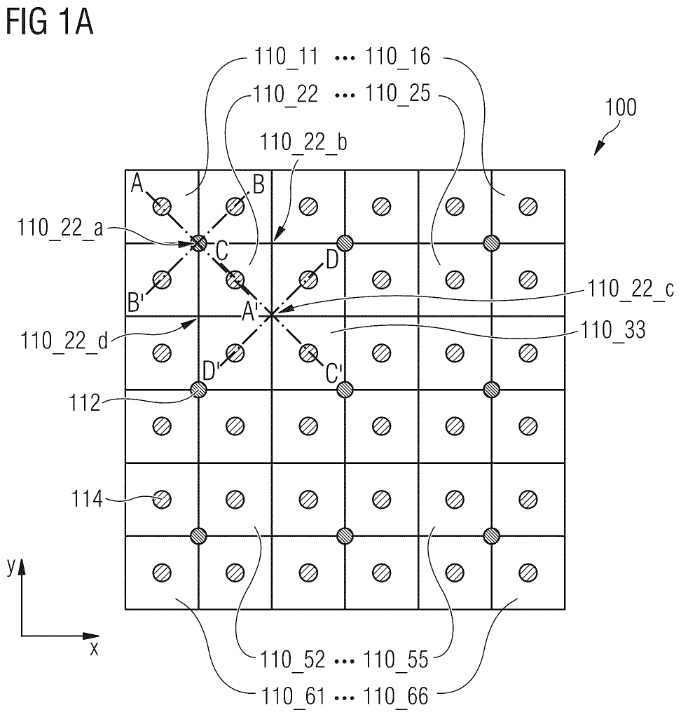

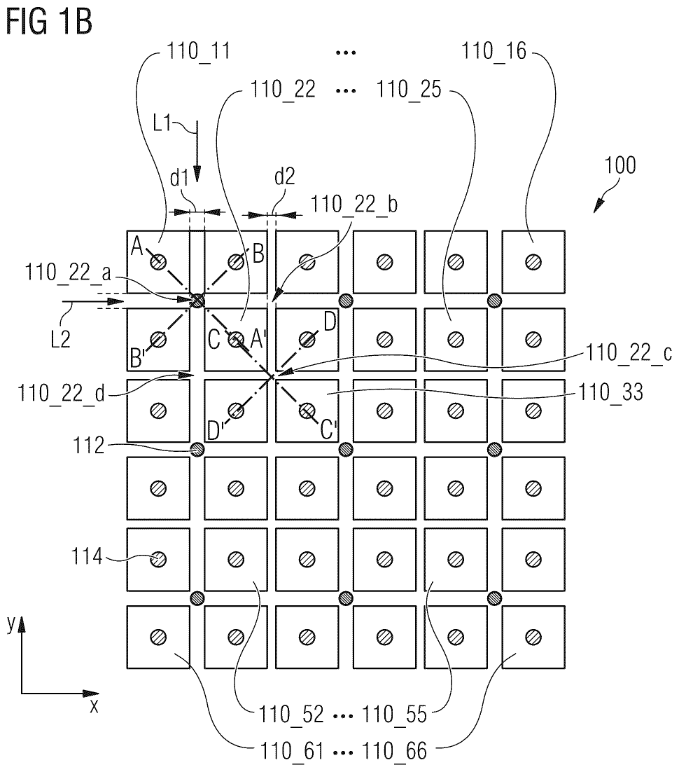

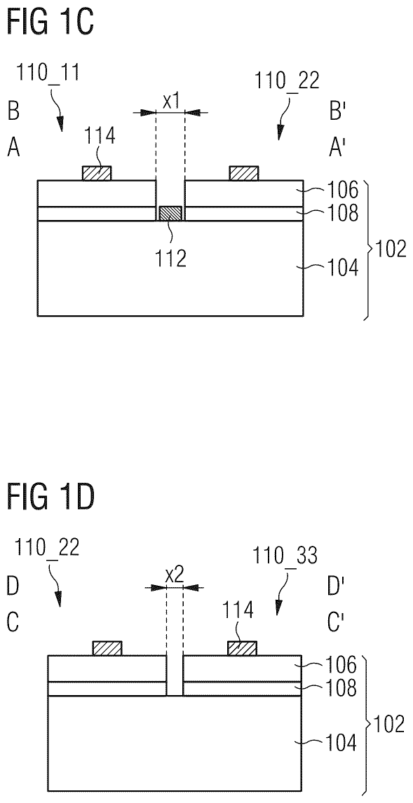

FIG. 1A and FIG. 1B illustrate partial top views of an exemplary semiconductor device 100, FIG. 1C illustrates a cross-sectional view of the semiconductor device 100 along the lines labelled A-A′ and B-B′ in FIGS. 1A and 1B, and FIG. 1D illustrates a cross-sectional view of the semiconductor device 100 along the lines labelled C-C′ and D-D′ in FIGS. 1A and 1B.

The semiconductor device 100 includes a semiconductor substrate 102. The semiconductor substrate 102 comprises an n-doped layer 104, a p-doped layer 106 and an active light emitting layer 108. The active light emitting layer 108 is arranged between the n-doped layer 104 and the p-doped layer 106. The active light emitting layer 108 may be referred to as active layer. In one example, the semiconductor substrate 102 is a GaN-based substrate. In one example, the n-doped layer 104, the p-doped layer 106 and the active light emitting layer 108 comprise a group III-V compound semiconductor material, such as gallium phosphide (GaP), gallium arsenide (GaAs), or gallium nitride (GaN). The n-doped layer 104, the p-doped layer 106 and/or the active light emitting layer 108 may be formed by deposition and/or epitaxy. The active light emitting layer 108 is configured to emit light and, in one example, comprises a quantum well structure, e. g., a single or a multiple quantum well structure. A semiconductor layer stack that comprises the n-doped layer 104, the p-doped layer 106 and the active light emitting layer 108 defines an active area or an active region of the semiconductor device 100. The semiconductor device 100 may be referred to as an optoelectronic device or an optical projection device.

It is to be noted that there may be additional layers and/or intermediate layers. In one example, a conversion layer (not illustrated) is arranged over at least parts of a main surface of the n-doped layer 104 that faces away from the p-doped layer 106. The conversion layer is configured to convert light having a first wavelength into light having a second wavelength.

The semiconductor device 100 includes a plurality of micro-LEDs (light-emitting diodes) 110_11-110_66. As illustrated in the example of FIGS. 1A and 1B, each of the plurality of micro-LEDs 110_11-110_66 has a rectangular shape, e. g., a square shape. The plurality of micro-LEDs 110_11-110_66 have a defined pitch such as less than 800 μm, less than 500 μm, less than 100 μm, less than 50 μm or even smaller. A portion of the semiconductor substrate 102 that is assigned to one of the plurality of micro-LEDs 110_11-110_66 may be referred to as a semiconductor mesa. The plurality of micro-LEDs 110_11-110_66 are monolithically integrated in the semiconductor substrate 102. That means, the plurality of micro-LEDs 110_11-110_66 are monolithically integrated on a same semiconductor wafer or on a same semiconductor die. The semiconductor device 100 may include tens, hundreds, thousands, tens of thousands, or even more micro-LEDs 110_11-110_66. The plurality of micro-LEDs 110_11-110_66 are arranged in a two-dimensional array along a first direction x and along a second direction y and each of the plurality of micro-LEDs 110_11-110_66 may represent or constitute a pixel of a display. In the example of FIGS. 1A and 1B, the second direction y is perpendicular to the first direction x. In one example, the plurality of micro-LEDs 110_11-110_66 are arranged in a matrix configuration.

As illustrated in the cross-sectional views of FIGS. 1C and 1D, the n-doped layer 104 is a contiguous layer that is common to the plurality of micro-LEDs 110_11-110_66. Each of the plurality of micro-LEDs 110_11-110_66 includes a part of the n-doped layer 104. In one example, the n-doped layer 104 may be structured in a way that it still forms a contiguous layer. The semiconductor device 100 includes cathode contacts 112 that allow for an electrical connection to the n-doped layer 104. FIGS. 1A through 1D show a schematic representation of the cathode contacts 112. The cathode contacts 112 may include pads for making electrical contact between the n-doped layer 104 and devices outside the semiconductor device 100, e. g., a further semiconductor device. The pads may be arranged over the semiconductor substrate 102 and may include one or more materials layers, e. g., such as Cu, Au, AuSn, etc. The cathode contacts 112 may include one or more materials layers, e. g., such as Cu, Au, AuSn, etc. In one example, the cathode contact 112 may be referred to as a cathode electrode. The cathode contacts 112 are electrically isolated from other structures of the semiconductor device 100, e. g., from anode contacts that will be described later herein. For ease of illustration, this electrical isolation is not illustrated in the figures.

While the n-doped layer 104 is a contiguous layer, the p-doped layer 106 is a structured layer including a plurality of portions that are electrically isolated from each other. While FIG. 1A shows the delimitation of the plurality of micro-LEDs 110_11-110_66 only schematically, FIG. 1B illustrates a top view and FIGS. 1C and 1D illustrate a cross-sectional view of the structured p-doped layer 106 including the plurality of portions of the structured p-doped layer 106. For ease of illustration, the electrical isolation between the portions is not illustrated in the figures. The portions of the structured p-doped layer 106 may be referred to as islands, sections or regions and the structured p-doped layer 106 may be referred to as patterned p-doped layer 106. Each of the plurality of micro-LEDs 110_11-110_66 includes its dedicated section of the structured p-doped layer 106. The active light emitting layer 108 is also a structured layer and the active light emitting layer 108 may be structured in a same or similar way as the p-doped layer 106.

The semiconductor device 100 includes anode contacts 114 that allow for an electrical connection to the portions of the structured p-doped layer 106. FIGS. 1A through 1D show a schematic representation of the anode contacts 114. Similar to the cathode contacts 112, the anode contacts 114 may include pads for making electrical contact between the portions of the structured p-doped layer 106 and devices outside the semiconductor device 100, e. g., a further semiconductor device. The pads may be arranged over the semiconductor substrate 102. The anode contacts 114 may include one or more materials layers, e. g., similar or same as the cathode contacts 112. In one example, the anode contact 114 may be referred to as an anode electrode. The anode contacts 114 are electrically isolated from each other and from other structures of the semiconductor device 100, e. g., from the cathode contacts 112. For ease of illustration, this electrical isolation is not illustrated in the figures. Each of the plurality of micro-LEDs 110_11-110_66 includes an anode contact 114 that is electrically connected to the section of the p-doped layer 106 that is dedicated to the respective micro-LEDs 110_11-110_66. In one example, the anode contacts 114 of the plurality of micro-LEDs 110_11-110_66 are configured to be controlled individually. For example, the plurality of micro-LEDs 110_11-110_66 can be switched on or switched off independently from each other via the anode contacts 144.

The plurality of micro-LEDs 110_11-110_66 comprises a first micro-LED 110_22-110_55 that is surrounded by other micro-LEDs of the plurality of micro-LEDs 110_11-110_66. In the example of FIGS. 1A and 1B, a first micro-LED 110_22 is surrounded by eight other micro-LEDs 110_11-110_13, 110_21, 110_23, 110_31-110_33 and the first micro-LED 110_22 is embedded in the plurality of micro-LEDs 110_11-110_66. That means, the eight other micro-LEDs 110_11-110_13, 110_21, 110_23, 110_31-110_33 are arranged adjacent to the first micro-LED 110_22. Corners of the surrounding micro-LEDs of the plurality of micro-LEDs 110_11-110_66 are arranged adjacent to corners of the first micro-LED 110_22. Sidewalls of the surrounding micro-LEDs of the plurality of micro-LEDs 110_11-110_66 face sidewalls of the first micro-LED 110_22. In the example of FIGS. 1A and 1B, some corners of each of the eight other micro-LEDs 110_11-110_13, 110_21, 110_23, 110_31-110_33 are arranged adjacent to the four corners of the first micro-LED 110_22. Some sidewalls of four 110_12, 110_21, 110_23, 110_32 of the eight other micro-LEDs 110_11-110_13, 110_21, 110_23, 110_31-110_33 are opposite the four sidewalls of the first micro-LED 110_22. The sidewalls may be referred to as sides or edges.

A corner associated with one of the plurality of micro-LEDs 110_11-110_66 is defined by a position where a first line intersects a second line. The first line is defined by a lateral space between a portion of the structured p-doped layer 106 assigned to the one of the plurality of micro-LEDs 110_11-110_66 and a further portion of the structured p-doped layer 106 assigned to a further one of the plurality of micro-LEDs 110_11-110_66 that is arranged adjacent to the one of the plurality of micro-LEDs 110_11-110_66. The second line is defined by a lateral space between the portion of the structured p-doped layer 106 assigned to the one of the plurality of micro-LEDs 110_11-110_66 and a yet further portion of the structured p-doped layer 106 assigned to a yet further one of the plurality of micro-LEDs 110_11-110_66 that is arranged adjacent to the one of the plurality of micro-LEDs 110_11-110_66. That means, the first line and the second line, respectively, are defined by a gap in the p-doped layer 106 which is located between neighboring portions of the structured p-doped layer 106. In other words, the first line and the second line, respectively, are defined by a space between sidewalls or edges of neighboring portions of the structured p-doped layer 106.

As illustrated in the example of FIG. 1B, the first line L1 is defined by a lateral space between a first portion of the p-doped layer 106 of the first micro-LED 110_22 and a fourth portion of the p-doped layer 106 of a fourth micro-LED 110_21. The fourth micro-LED 110_21 is one of the eight other micro-LEDs 110_11-110_13, 110_21, 110_23, 110_31-110_33 that surround the first micro-LED 110_22. The second line L2 is defined by a lateral space between the first portion of the p-doped layer 106 of the first micro-LED 110_22 and a fifth portion of the p-doped layer 106 of a fifth micro-LED 110_12. The fifth micro-LED 110_21 is one of the eight other micro-LEDs 110_11-110_13, 110_21, 110_23, 110_31-110_33 that surround the first micro-LED 110_22. A corner 110_22_a associated with the first micro-LED 110_22 is defined by a position where the first line L1 intersects the second line L2. The fourth portion of the p-doped layer 106 of the fourth micro-LED 110_21 and the fifth portion of the p-doped layer 106 of the fifth micro-LED 110_12 do not have sidewalls facing each other. In the example of FIG. 1B, the first line L1 intersects the second line L2 at an angle of 90 degrees. There are four corners 110_22_a, 110_22_b, 110_22_c, 110_22_d associated with the first micro-LED 110_22. Generally, in the example of FIG. 1B, four corners are associated with each of the plurality of micro-LEDs 110_22-110_55 that are completely surrounded by other ones of the plurality of micro-LEDs 110_11-110_66. The plurality of micro-LEDs 110_22-110_55 that are completely surrounded by other ones of the plurality of micro-LEDs 110_11-110_66 may be referred to as embedded micro-LEDs 110_22-110_55.

Generally, at least one corner associated with each of the embedded micro-LEDs 110_22-110_55 does not comprise (i.e., is devoid of) any cathode contact 112 that is electrically connected to the n-doped layer 104. The cathode contact 112 is not required at the at least one corner as an electrical connection is provided via the contiguous n-doped layer 104. In the example of FIG. 1B, three corners 110_22_b, 110_22_c, 110_22_d associated with the first micro-LED 110_22 do not comprise any cathode contact 112. That means, the three corners 110_22_b, 110_22_c, 110_22_d associated with the first micro-LED 110_22 are devoid of any cathode contact 112. One corner 110_22_a associated with the first micro-LED 110_22 comprises a cathode contact 112 that is electrically connected to the n-doped layer 104. This cathode contact 112 may be referred to as shared cathode contact 112 or common cathode contact 112 as it is common to all the micro-LEDs 110_11, 110_12, 110_21, 10_22 that are arranged adjacent to the one corner 110_22_a associated with the first micro-LED 110_22. In the example of FIG. 1B, each of the plurality of micro-LEDs 110_11-110_66 has one associated corner that comprises a cathode contact 112 that is electrically connected to the n-doped layer 104. The cathode contacts 112 are arranged in gaps in the p-doped layer 106. In one example, at least one corner associated with each of the embedded micro-LEDs 110_22-110_55 does not comprise any cathode contact 112 that is electrically connected to the n-doped layer 104 and at least one further corner associated with each of the embedded micro-LEDs 110_22-110_55 comprises a cathode contact 112 that is electrically connected to the n-doped layer 104.

Generally, a lateral distance between the first portion of the p-doped layer 106 of the first micro-LED 110_22 and a further portion of the p-doped layer 106 of a further micro-LED is larger at a corner associated with the first micro-LED 110_22 that comprises a cathode contact 112 than at a further corner associated with the first micro-LED 110_22 that does not comprise any cathode contact 112. The further micro-LED is one of the other micro-LEDs that surround the first micro-LED 110_22. In the example of FIG. 1B, there is a first lateral distance d1 between the first portion of the p-doped layer 106 of the first micro-LED 110_22 and the fourth portion of the p-doped layer 106 of the fourth micro-LED 110_21 at the one corner 110_22_a associated with the first micro-LED 110_22 that comprises a cathode contact 112. There is a second lateral distance d2 between the first portion of the p-doped layer 106 of the first micro-LED 110_22 and a sixth portion of the p-doped layer 106 of a sixth micro-LED 110_23 at the one corner 110_22_b associated with the first micro-LED 110_22 that does not comprise any cathode contact 112. Both, the fourth micro-LED 110_21 and the sixth micro-LED 110_23 are one of the eight micro-LEDs 110_11-110_13, 110_21, 110_23, 110_31-110_33 that surround the first micro-LED 110_22. The first lateral distance d1 is larger than the second lateral distance d2. That means, sidewalls or edges of neighboring portions of the structured p-doped layer 106 can be arranged closer together at corners associated with the first micro-LED 110_22 that are devoid of any cathode contact 112 than at corners associated with the first micro-LED 110_22 that comprise a cathode contact 112. In other words, gaps between neighboring portions of the structured p-doped layer 106 are smaller at corners associated with the first micro-LED 110_22 that are devoid of any cathode contact 112 than at corners associated with the first micro-LED 110_22 that comprise a cathode contact 112. As portions of the p-doped layer 106 can be arranged closer together, the area of the p-doped layer 106 in relation to the total area of the semiconductor device 100 can be increased. An area of the active light emitting layer 108 that is arranged below the p-doped layer 106 can be increased accordingly. As a result, the active area of the semiconductor device 100 can be increased and the light emission of the semiconductor device 100 can be improved. Areas of the semiconductor device 100 that include a cathode contact 112 do not contribute to the light emission of the semiconductor device 100. To increase the light emission of the semiconductor device 100 the number of cathode contacts 112 may be reduced or minimized.

FIG. 1C illustrates a cross-sectional view of the semiconductor device 100 along the lines labelled A-A′ and B-B′ in FIGS. 1A and 1B, and FIG. 1D illustrates a cross-sectional view of the semiconductor device 100 along the lines labelled C-C′ and D-D′ in FIGS. 1A and 1B. As illustrated in FIG. 1C, there is a third lateral distance x1 between a corner of the first portion of the p-doped layer 106 of the first micro-LED 110_22 and a corner of a further portion of the p-doped layer 106 of a further micro-LED 110_11. The further micro-LED 110_11 is one of the eight micro-LEDs 110_11-110_13, 110_21, 110_23, 110_31-110_33 that surrounds the first micro-LED 110_22. The third lateral distance x1 is measured at the corner 110_22_a associated with the first micro-LED 110_22 that comprises a cathode contact 112. Besides, there is a fourth lateral distance x2 between a corner of the first portion of the p-doped layer 106 of the first micro-LED 110_22 and a corner of a yet further portion of the p-doped layer 106 of a yet further micro-LED 110_33. The yet further micro-LED 110_33 is one of the eight micro-LEDs 110_11-110_13, 110_21, 110_23, 110_31-110_33 that surrounds the first micro-LED 110_22. The fourth lateral distance x2 is measured at the corner 110_22_c associated with the first micro-LED 110_22 that does not comprise a cathode contact 112. The third lateral distance x1 is larger than the fourth lateral distance x2. That means, corners of neighboring portions of the structured p-doped layer 106 can be arranged closer together at corners associated with the first micro-LED 110_22 that are devoid of any cathode contact 112 than at corners associated with the first micro-LED 110_22 that comprise a cathode contact 112. The small distance between portions of the p-doped layer 106 enables an increase of the active area of the semiconductor device 100 and an improved light generation of the semiconductor device 100.

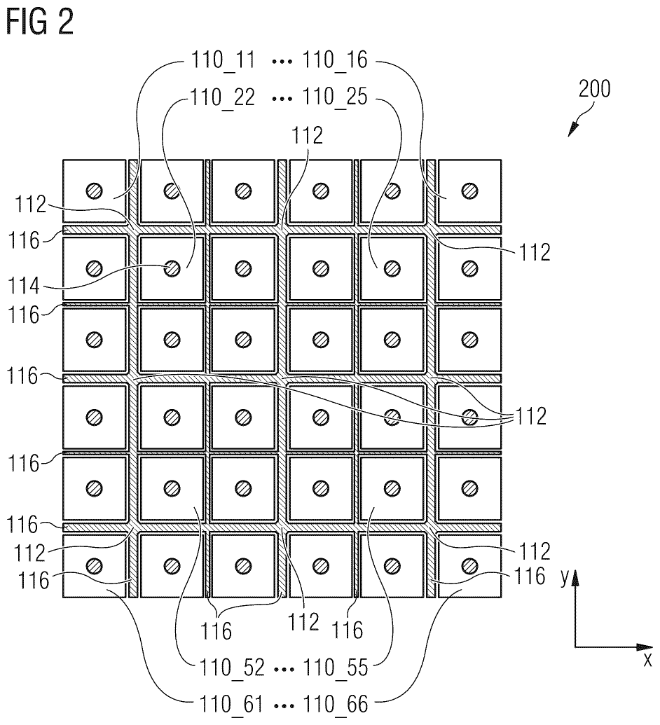

FIG. 2 illustrates a partial top view of a further exemplary semiconductor device 200. Similar to the semiconductor device 100 as illustrated and described in connection with FIGS. 1A through 1D, the semiconductor device 200 includes a plurality of micro-LEDs 110_11-110_66 that are arranged in a matrix configuration. The semiconductor device 200 further includes anode contacts 114 that allow for an electrical connection to portions of a structured p-doped layer 106 of the semiconductor device 200. Each of the plurality of micro-LEDs 110_11-110_66 includes its dedicated section of the structured p-doped layer 106. The semiconductor device 200 further includes cathode contacts 112 that allow for an electrical connection to a contiguous n-doped layer 104 of the semiconductor device 200. The plurality of micro-LEDs 110_22-110_55 that are completely surrounded by other ones of the plurality of micro-LEDs 110_11-110_66 may be referred to as embedded micro-LEDs 110_22-110_55. In the example of FIG. 2, at most one corner associated with each of the embedded micro-LEDs 110_22-110_55 comprises a cathode contact 112. That means, three corners associated with each of the embedded micro-LEDs 110_22-110_55 do not comprise any cathode contact 112. In contrast to the semiconductor device 100 as illustrated and described in connection with FIGS. 1A through 1D, the semiconductor device 200 comprises interconnection lines 116 arranged in the space between portions of the structured p-doped layer 106. As illustrated in FIG. 2, the interconnection lines 116 may be arranged in a grid configuration and may be referred to as interconnection grid. The interconnection lines 116 are electrically connected to the n-doped layer 104 and to the cathode contacts 112 and allow for an improved electrical contact between the n-doped layer 104 and devices outside the semiconductor device 200. Thus, a stable operation of the semiconductor device 200 is enabled. The interconnection lines 116 are electrically isolated from other structures of the semiconductor device 100, e. g., from the portions of the structured p-doped layer 106. For ease of illustration, this electrical isolation is not illustrated in FIG. 2.

In one example, all interconnection lines 116 of the semiconductor device 200 have a same width. In other examples, the interconnection lines 116 of the semiconductor device 200 have different widths and/or a varying width along their longitudinal expansions. In the example of FIG. 2, the width of interconnection lines 116 that cross a cathode contact 112 is larger than the width of interconnection lines 116 that do not cross any cathode contact 112. The width of the interconnection lines 116 may be same, smaller, or wider than a lateral dimension of the cathode contacts 112.

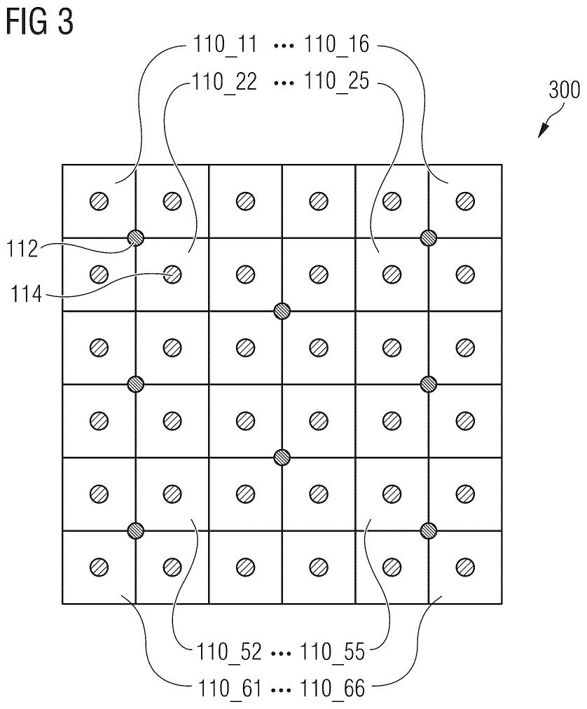

FIG. 3 illustrates a partial top view of a further exemplary semiconductor device 300. Similar to the semiconductor device 100 as illustrated and described in connection with FIGS. 1A through 1D, the semiconductor device 300 includes a plurality of micro-LEDs 110_11-110_66 that are arranged in a matrix configuration. The semiconductor device 300 further includes anode contacts 114 that allow for an electrical connection to portions of a structured p-doped layer 106 of the semiconductor device 300. Each of the plurality of micro-LEDs 110_11-110_66 includes its dedicated section of the structured p-doped layer 106. Similar to FIG. 1A, FIG. 3 shows the delimitation of the plurality of micro-LEDs 110_11-110_66 only schematically and the portions of the structured p-doped layer 106 are not illustrated in FIG. 3. The semiconductor device 300 further includes a plurality of cathode contacts 112 that allow for an electrical connection to a contiguous n-doped layer 104 of the semiconductor device 300. In the example of FIG. 3, the plurality of cathode contacts 112 are arranged offset to each other. The plurality of cathode contacts 112 may be arranged offset to each other in the first direction x and/or in the second direction y. The plurality of micro-LEDs 110_22-110_55 that are completely surrounded by other ones of the plurality of micro-LEDs 110_11-110_66 may be referred to as embedded micro-LEDs 110_22-110_55. In the example of FIG. 3, at most one corner associated with each of the embedded micro-LEDs 110_22-110_55 comprises a cathode contact 112.

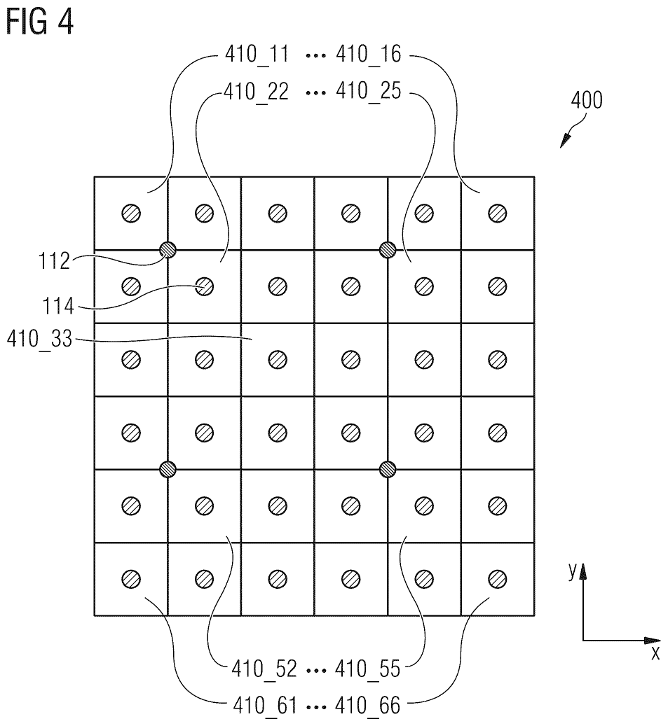

FIG. 4 illustrates a partial top view of a further exemplary semiconductor device 400. Similar to the semiconductor device 100 as illustrated and described in connection with FIGS. 1A through 1D, the semiconductor device 400 includes a plurality of micro-LEDs 410_11-410_66 that are arranged in a matrix configuration. The semiconductor device 400 further includes anode contacts 114 that allow for an electrical connection to portions of a structured p-doped layer 106 of the semiconductor device 400. Each of the plurality of micro-LEDs 410_11-410_66 includes its dedicated section of the structured p-doped layer 106. Similar to FIGS. 1A and 3, FIG. 4 shows the delimitation of the plurality of micro-LEDs 410_11-410_66 only schematically and the portions of the structured p-doped layer 106 are not illustrated in FIG. 4. The semiconductor device 400 further includes a plurality of cathode contacts 112 that allow for an electrical connection to a contiguous n-doped layer 104 of the semiconductor device 400. The plurality of micro-LEDs 410_22-410_55 that are completely surrounded by other micro-LEDs of the plurality of micro-LEDs 410_11-410_66 may be referred to as embedded micro-LEDs 410_22-410_55. In the example of FIG. 4, the semiconductor device 400 comprises at least one second micro-LED 410_33 and no corner associated with the second micro-LED 410_33 comprises a cathode contact 112. The corners associated with the at least one second micro-LED 410_33 do not require any cathode contact 112 as a part of the n-doped layer 104 that is included in the second micro-LED 410_33 is configured to be electrically connected to devices outside the semiconductor device 400 via the contiguous n-doped layer 104.

The plurality of portions of the structured p-doped layer 106 may have a rectangular shape, e. g., a square shape, when seen from top, as shown in FIGS. 1B and 2. In other examples, the plurality of portions of the structured p-doped layer 106 may have a different shape when seen from top, e. g., a different angular shape like a triangular, hexagonal, octagonal etc. shape. In a top view, portions of the active light emitting layer 108 that are arranged below the plurality of portions of the structured p-doped layer 106 may have a similar or same shape as the plurality of portions of the structured p-doped layer 106. In the top view, each of the plurality of portions of the structured p-doped layer 106 and each of the respective portions of the active light emitting layer 108 may have a same or different surface area. In the examples of FIGS. 1A through 1D and FIGS. 2 through 4, the plurality of micro-LEDs 110_11-110_66 are arranged in a two-dimensional array along the first direction x and along the second direction y and the second direction y is perpendicular to the first direction x. In other examples, the angle between the first direction x and the second direction y may be different, e. g., 30 degrees or 60 degrees.

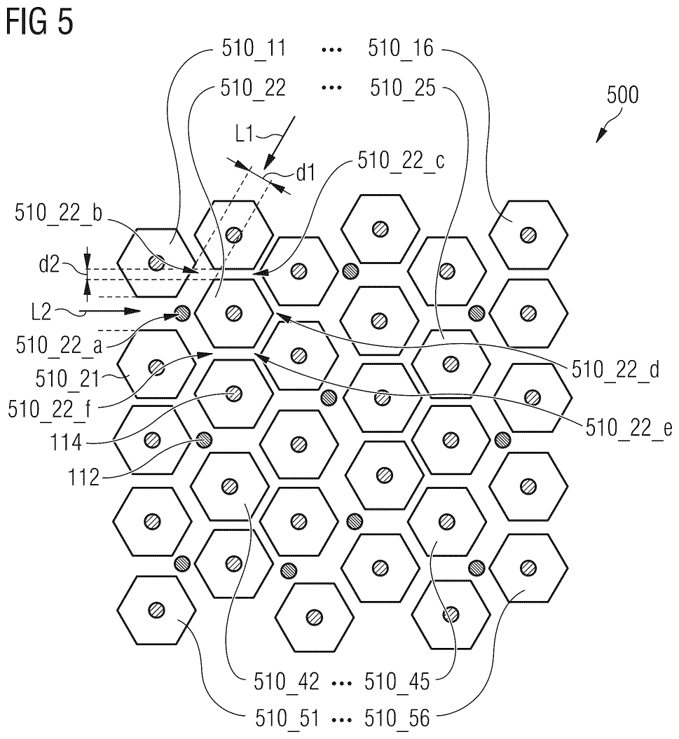

FIG. 5 illustrates a partial top view of a further exemplary semiconductor device 500. In the example of FIG. 5, a semiconductor device 500 includes a plurality of micro-LEDs 510_11-510_56 that have a hexagonal shape. The plurality of micro-LEDs 510_11-510_56 are arranged in an array configuration. The semiconductor device 500 further includes anode contacts 114 that allow for an electrical connection to portions of a structured p-doped layer 106 of the semiconductor device 500. Each of the plurality of micro-LEDs 510_11-510_56 includes its dedicated section of the structured p-doped layer 106 and of a structured active light emitting layer 108. The semiconductor device 500 further includes a plurality of cathode contacts 112 that allow for an electrical connection to a contiguous n-doped layer 104 of the semiconductor device 500. The plurality of micro-LEDs 510_22-510_45 that are completely surrounded by other micro-LEDs of the plurality of micro-LEDs 510_11-510_56 may be referred to as embedded micro-LEDs 510_22-510_45. For example, a first micro-LED 510_22 is surrounded by six other micro-LEDs 510_11-510_13, 510_21, 510_23, 510_32. Some corners of each of the six surrounding micro-LEDs 510_11-510_13, 510_21, 510_23, 510_32 are arranged adjacent to the six corners of the first micro-LED 510_22. Some sidewalls of each of the six surrounding micro-LEDs 510_11-510_13, 510_21, 510_23, 510_32 are arranged opposite six sidewalls of the first micro-LED 510_22.

A corner associated with one of the plurality of micro-LEDs 510_11-510_56 is defined by a position where a first line intersects a second line. For example, a corner 510_22_a of the first micro-LED 510_22 is defined by a position where the first line L1 intersects the second line L2. The first line L1 is defined by a lateral space between a first portion of the p-doped layer 106 of the first micro-LED 510_22 and a fourth portion of the p-doped layer 106 of a fourth micro-LED 510_11. The fourth micro-LED 510_11 is one of the six micro-LEDs 510_11-510_13, 510_21, 510_23, 510_32 that surround the first micro-LED 510_22. The second line L2 is defined by a lateral space between the first portion of the p-doped layer 106 of the first micro-LED 510_22 and a fifth portion of the p-doped layer 106 of a fifth micro-LED 510_12. The fifth micro-LED 510_12 is one of the six micro-LEDs 510_11-510_13, 510_21, 510_23, 510_32 that surround the first micro-LED 510_22. The corner 510_22_a associated with the first micro-LED 510_22 is defined by a position where the first line L1 intersects the second line L2. The fourth portion of the p-doped layer 106 of the fourth micro-LED 510_11 and the fifth portion of the p-doped layer 106 of the fifth micro-LED 510_12 have sidewalls facing each other. In the example of FIG. 5, the first line L1 intersects the second line L2 at an angle of 30 degrees. There are six corners 510_22_a-510_22_f associated with the first micro-LED 510_22. Generally, in the example of FIG. 5, six corners are associated with each of the plurality of micro-LEDs 510_22-510_45 that are completely surrounded by other ones of the plurality of micro-LEDs 510_11-510_56. The plurality of micro-LEDs 510_22-510_45 that are completely surrounded by other ones of the plurality of micro-LEDs 510_11-510_56 may be referred to as embedded micro-LEDs 510_22-510_45.

Generally, at least one corner associated with each of the embedded micro-LEDs 510_22-510_45 does not comprise any cathode contact 112 that is electrically connected to the n-doped layer 104. The cathode contact 112 is not required at the at least one corner as an electrical connection is provided via the contiguous n-doped layer 104. In the example of FIG. 5, five corners 510_22_b-510_22_f associated with the first micro-LED 510_22 do not comprise any cathode contact 112. Lateral distances between neighboring portions of the structured p-doped layer 106 are smaller at corners 510_22_b-510_22_f associated with the first micro-LED 510_22 that are devoid of any cathode contact 112 than at corners 510_22_a associated with the first micro-LED 510_22 that comprise a cathode contact 112. Omitting cathode contacts 112 at corners 510_22_b-510_22_f associated with the first micro-LED 510_22 provides for an increase of the active area and the light emission of the semiconductor device 500.

FIGS. 1A through 1D and FIGS. 2 through 5 show only exemplary embodiments and various modifications will be apparent to persons skilled in the art. For example, when seen from top, the cathode contacts 112 and/or the anode contacts 114 may have a different shape to that shown in FIGS. 1A through 1D and FIGS. 2 through 5. For example, the cathode contacts 112 and/or the anode contacts 114 may have an angular shape. For example, the number of cathode contacts 112 and/or anode contacts 114 may be different from what is illustrated and described in connection with FIGS. 1A through 1D and FIGS. 2 through 5. For example, there may be more than one anode contact 114 that is electrically connected to a respective section of the p-doped layer 106. For example, more than one corner associated with one of the embedded micro-LEDs may comprise a cathode contact 112. In one example, at least one corner associated with each of the embedded micro-LEDs does not comprise any cathode contact 112 that is electrically connected to the n-doped layer 104 and at least one further corner associated with each of the embedded micro-LEDs does comprise a cathode contact 112 that is electrically connected to the n-doped layer 104.

For example, positions of the cathode contacts 112 and/or the anode contacts 114 may be different from what is illustrated and described in connection with FIGS. 1A through 1D and FIGS. 2 through 5.

Features of the exemplary embodiments as illustrated and described in connection with FIGS. 1A through 1D and FIGS. 2 through 5 may be combined. For example, interconnection lines 116 as illustrated and described in connection with FIG. 2 may be included in the arrangement of hexagonal micro-LEDs of FIG. 5. For example, the plurality of embedded hexagonal micro-LEDs of FIG. 5 include at least one second micro-LED and no corner associated with the second micro-LED comprises a cathode contact 112 similar to the second micro-LED 410_33 of FIG. 4.

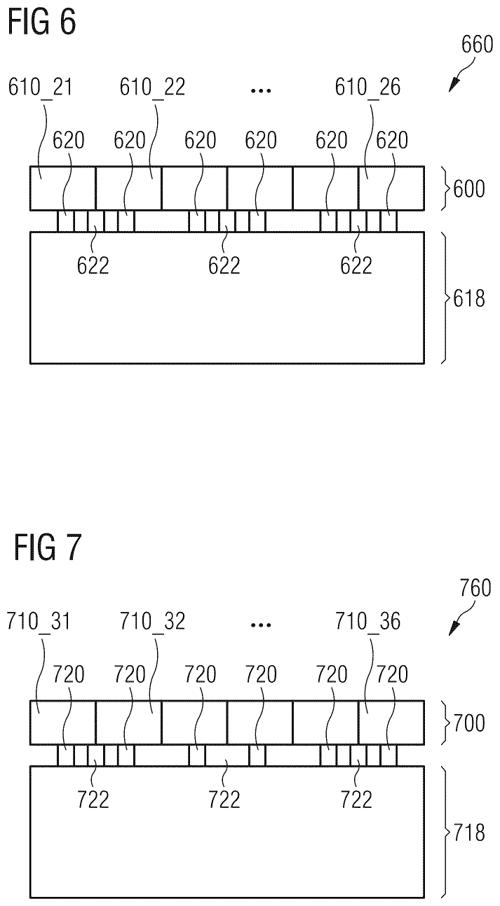

FIG. 6 illustrates a partial cross-sectional view of a further exemplary semiconductor device 660. The semiconductor device 660 may be referred to as a semiconductor device arrangement 660 and includes a semiconductor device 600 that is similar to one of the semiconductor devices 100-500 as illustrated and described in connection with FIGS. 1A through 1D and FIGS. 2 through 5. The semiconductor device arrangement 660 further includes a driver device 618 that is configured to individually drive a plurality of micro-LEDs 610_21-610_26 of the semiconductor device 600. Each of the anode electrodes of the semiconductor device 600 is electrically connected to a corresponding anode electrode of the driver device 618 via an anode interconnect 620. The anode interconnects 620 may be referred to as individual anode interconnects 620. In one example, the anode interconnects 620 include pads of the semiconductor device 600 and/or the driver device 618. The semiconductor device arrangement 660 further includes cathode interconnects 622 that electrically connect cathode electrodes of the semiconductor device 600 to corresponding cathode electrodes of the driver device 618. In one example, the cathode interconnects 622 include pads of the semiconductor device 600 and/or the driver device 618.

The plurality of micro-LEDs 610_21-610_26 includes a first micro-LEDs 610_22 that is similar or same as the first micro-LED 110_22, 410_22, 510_22 as illustrated and described in connection with FIGS. 1A through 1D and FIGS. 2 through 5. At least one corner associated with the first micro-LED 610_22 does not comprise any cathode electrode. In the example of FIG. 6, no cathode interconnect 622 to the driver device is arranged over this at least one corner associated with the first micro-LED 610_22. That means, the cathode interconnect 622 is omitted over this at least one corner associated with the first micro-LED 610_22. The cathode interconnects 622 that are included in the semiconductor device arrangement 660 of FIG. 6 may be referred to as shared cathode interconnects 622 as they are shared between adjacent micro-LEDs. The omission of cathode interconnects, i. e., the use of shared interconnects, allows an area-efficient and cost-efficient implementation of the semiconductor device arrangement 660.

FIG. 7 illustrates a partial cross-sectional view of a further exemplary semiconductor device 760. The semiconductor device 760 may be referred to as a semiconductor device arrangement 760. Similar to the semiconductor device arrangement 660 of FIG. 6, the semiconductor device arrangement 760 includes a semiconductor device 700 having a plurality of micro-LEDs 710_31-710_36 and a driver device 718. The semiconductor device arrangement 760 further includes individual anode interconnects 720 and shared cathode interconnects 722. Differently, however, the semiconductor device arrangement 760 of FIG. 7 includes a third micro-LED 710_33 that is similar or same as the second micro-LED 410_33 as illustrated and described in connection with FIG. 4. No corner associated with the third micro-LED 710_33 comprises a cathode contact. In the example of FIG. 7, no cathode interconnect 722 to the driver device is arranged over any corner associated with the third micro-LED 710_33. The omission of cathode interconnects over the third micro-LED 710_33 allows for a more efficient implementation in terms of area and cost.

Examples of the present invention are summarized here. Other examples can also be understood from the entirety of the specification and the claims filed herein.

Example 1: A semiconductor device, comprising: a semiconductor substrate, comprising: an n-doped layer; a p-doped layer; and an active light emitting layer arranged between the n-doped layer and the p-doped layer; and a plurality of micro-LEDs monolithically integrated in the semiconductor substrate; wherein the plurality of micro-LEDs are arranged in a two-dimensional array along a first direction and along a second direction; and wherein the plurality of micro-LEDs comprise a first micro-LED that is surrounded by other micro-LEDs of the plurality of micro-LEDs, wherein a corner associated with the first micro-LED does not comprise (i.e., is devoid of) any cathode contact that is electrically connected to the n-doped layer.

Example 2: The semiconductor device of the preceding example, wherein the second direction is perpendicular to the first direction.

Example 3: The semiconductor device of any of the preceding examples, wherein each of the plurality of micro-LEDs comprises an anode contact that is electrically connected to the p-doped layer.

Example 4: The semiconductor device of the preceding example, wherein the anode contacts of the plurality of micro-LEDs are configured to be controlled individually.

Example 5: The semiconductor device of any of the preceding examples, wherein the first micro-LED is surrounded by at least eight other micro-LEDs of the plurality of micro-LEDs.

Example 6: The semiconductor device of any of the preceding examples, wherein the plurality of micro-LEDs comprise a second micro-LED, wherein no corner associated with the second micro-LED comprises a cathode contact.

Example 7: The semiconductor device of the preceding example, wherein the second micro-LED is surrounded by other micro-LEDs of the plurality of micro-LEDs.

Example 8: The semiconductor device of any of the preceding examples, wherein each of the plurality of micro-LEDs has at most one associated corner that comprises a cathode contact.

Example 9: The semiconductor device of any of the preceding examples, wherein each of the plurality of micro-LEDs has a rectangular shape.

Example 10: The semiconductor device of any of the preceding examples, wherein the semiconductor substrate is a GaN-based substrate.

Example 11: The semiconductor device of any of the preceding examples, wherein the active light emitting layer comprises a quantum well structure.

Example 12: The semiconductor device of any of the preceding examples, wherein the n-doped layer is a contiguous layer.

Example 13: The semiconductor device of any of the preceding examples, wherein the p-doped layer is a structured layer.

Example 14: The semiconductor device of the preceding example, wherein a corner associated with the first micro-LED is defined by a position where a first line defined by a lateral space between a first portion of the p-doped layer of the first micro-LED and a fourth portion of the p-doped layer of a fourth micro-LED intersects a second line defined by a lateral space between the first portion of the p-doped layer of the first micro-LED and a fifth portion of the p-doped layer of a fifth micro-LED, wherein both the fourth micro-LED and the fifth micro-LED are one of the other micro-LEDs that surround the first micro-LED.

Example 15: The semiconductor device of any of the two preceding examples, wherein a lateral distance between a first portion of the p-doped layer of the first micro-LED and a further portion of the p-doped layer of a further micro-LED is larger at a corner associated with the first micro-LED that comprises a cathode contact than at a further corner associated with the first micro-LED that does not comprise any cathode contact, wherein the further micro-LED is one of the other micro-LEDs that surround the first micro-LED.

Example 16: The semiconductor device of any of the preceding examples, further comprising a plurality of cathode contacts that are arranged offset to each other.

Example 17: The semiconductor device of any of the preceding examples, further comprising a driver device configured to drive the plurality of micro-LEDs individually.

Example 18: The semiconductor device of the preceding example, wherein no cathode interconnect to the driver device is arranged over the corner associated with the first micro-LED.

Example 19: The semiconductor device of the preceding example, wherein the plurality of micro-LEDs comprise a third micro-LED, wherein no cathode interconnect to the driver device is arranged over any corner associated with the third micro-LED.

While this invention has been described with reference to illustrative examples, this description is not intended to be construed in a limiting sense. Various modifications and combinations of the illustrative examples, as well as other examples of the invention, will be apparent to persons skilled in the art upon reference to the description. It is therefore intended that the appended claims encompass any such modifications or examples.

What is claimed is:

1. A semiconductor device, comprising:
a semiconductor substrate comprising an n-doped layer, a p-doped layer, and an active light emitting layer arranged between the n-doped layer and the p-doped layer; and
a plurality of micro-LEDs monolithically integrated in the semiconductor substrate;
wherein the plurality of micro-LEDs is arranged in a two-dimensional array along a first direction and along a second direction,
wherein the plurality of micro-LEDs comprises a first micro-LED that is surrounded by other micro-LEDs of the plurality of micro-LEDs,
wherein a corner associated with the first micro-LED does not comprise any cathode contact that is electrically connected to the n-doped layer.

2. The semiconductor device of claim 1, wherein the second direction is perpendicular to the first direction.

3. The semiconductor device of claim 1, wherein each micro-LED of the plurality of micro-LEDs comprises an anode contact that is electrically connected to the p-doped layer.

4. The semiconductor device of claim 3, wherein the anode contacts are configured to be controlled individually.

5. The semiconductor device of claim 1, wherein the first micro-LED is surrounded by at least eight other micro-LEDs of the plurality of micro-LEDs.

6. The semiconductor device of claim 1, wherein the plurality of micro-LEDs further comprises a second micro-LED, wherein no corner associated with the second micro-LED comprises a cathode contact.

7. The semiconductor device of claim 6, wherein the second micro-LED is surrounded by other micro-LEDs of the plurality of micro-LEDs.

8. The semiconductor device of claim 1, wherein each of the plurality of micro-LEDs has at most one associated corner that comprises a cathode contact.

9. The semiconductor device of claim 1, wherein each micro-LED that is surrounded by other micro-LEDs of the plurality of micro-LEDs comprises:
an associated corner that comprises a cathode contact that is electrically connected to the n-doped layer; and
a further associated corner that does not comprise any cathode contact that is electrically connected to the n-doped layer.

10. The semiconductor device of claim 1, wherein each of the plurality of micro-LEDs has a rectangular shape.

11. The semiconductor device of claim 1, wherein the semiconductor substrate is a GaN-based substrate.

12. The semiconductor device of claim 1, wherein the active light emitting layer comprises a quantum well structure.

13. The semiconductor device of claim 1, wherein the n-doped layer is a contiguous layer.

14. The semiconductor device of claim 1, wherein the p-doped layer is a structured layer.

15. The semiconductor device of claim 14, wherein a corner associated with the first micro-LED is defined by a position where a first line defined by a lateral space between a first portion of the p-doped layer of the first micro-LED and a fourth portion of the p-doped layer of a fourth micro-LED intersects a second line defined by a lateral space between the first portion of the p-doped layer of the first micro-LED and a fifth portion of the p-doped layer of a fifth micro-LED, and wherein both the fourth micro-LED and the fifth micro-LED are one of the other micro-LEDs that surround the first micro-LED.

16. The semiconductor device of claim 14, wherein a lateral distance between a first portion of the p-doped layer of the first micro-LED and a further portion of the p-doped layer of a further micro-LED is larger at a corner associated with the first micro-LED that comprises a cathode contact than at a further corner associated with the first micro-LED that does not comprise any cathode contact, and wherein the further micro-LED is one of the other micro-LEDs that surround the first micro-LED.

17. The semiconductor device of claim 1, further comprising a plurality of cathode contacts that are arranged offset to each other.

18. The semiconductor device of claim 1, further comprising a driver device configured to drive the plurality of micro-LEDs individually.

19. The semiconductor device of claim 18, wherein no cathode interconnect to the driver device is arranged over the corner associated with the first micro-LED.

20. The semiconductor device of claim 19, wherein the plurality of micro-LEDs further comprises a third micro-LED, and wherein no cathode interconnect to the driver device is arranged over any corner associated with the third micro-LED.
